(19) United States
(12) Patent Application Publication
(10) Pub. No.: US 2024/0065033 A1
(43) Pub. Date: Feb. 22, 2024

(54) DISPLAY PANEL AND MANUFACTURING METHOD THEREOF

(71) Applicants: HUIZHOU CHINA STAR OPTOELECTRONICS DISPLAY CO., LTD., Huizhou (CN); SHENZHEN CHINA STAR OPTOELECTRONICS SEMICONDUCTOR DISPLAY TECHNOLOGY CO., LTD., Shenzhen (CN)

(72) Inventors: Jingyuan HU, Huizhou (CN); Xiaoxing ZHANG, Huizhou (CN); Fanjing WU, Huizhou (CN)

(73) Assignees: HUIZHOU CHINA STAR OPTOELECTRONICS DISPLAY CO., LTD., Huizhou (CN); SHENZHEN CHINA STAR OPTOELECTRONICS SEMICONDUCTOR DISPLAY TECHNOLOGY CO., LTD., Shenzhen (CN)

(21) Appl. No.: 18/175,523

(22) Filed: Feb. 27, 2023

(30) Foreign Application Priority Data
Aug. 18, 2022 (CN) 202210990429.4

(51) Int. Cl. H10K 59/122; H10K 59/12

(52) U.S. Cl. CPC H10K 59/122; H10K 59/1201; H10K 2102/351

(57) ABSTRACT

Provided is a display panel comprising an anode layer, a sacrificial layer disposed on an anode layer, a pixel definition layer covering the sacrificial layer and the anode layer, and a light-emitting functional layer disposed in the groove and the light-emitting area opening, and a manufacturing method thereof, wherein the sacrificial layer is formed with a groove at a position corresponding to the light-emitting area opening. In this way, the sacrificial layer forming at the light-emitting area opening can be removed to form a groove at the same time in the process of forming the light-emitting area opening by exposure and development, so that it is possible to ensure that no pixel definition layer remains on the anode layer at the light-emitting area opening, thereby solving the problem that the light-emitting functional layer cannot be spread.

### CROSS-REFERENCE TO RELATED APPLICATIONS

The present application claims the benefit of priority to Chinese patent application 202210990429.4, filed on Aug. 18, 2022, which is incorporated herein by reference in its entirety.

### TECHNICAL FIELD

The present application relates to a technical field of display, and in particular, to a manufacturing method thereof.

### BACKGROUND

Currently, mass-produced ink-jet printing products use organic photoresists as pixel definition layers, and commonly used organic photoresists are negative photoresists. After a light-emitting area opening is defined in a pixel defination layer by exposure and development, tiny residues of the pixel defination layer are easily generated in the the light-emitting area opening.

Due to hydrophobic property of pixel definition layer materials, when a light-emitting functional layer is subsequently printed on an anode layer through the light-emitting area opening, the pixel definition layer remaining on the anode layer may cause printing materials to fail to spread, thereby causing various defects and affecting product yield.

### Technical Problem

It is an object of the present application to provide a display panel and a manufacturing method thereof, which aims to ensure that no pixel definition layer remains on an anode layer located in a light-emitting area opening, and to solve a problem that a light-emitting functional layer cannot be spread.

### Technical Solution

In one aspect, the present application provides a display panel, wherein the display panel comprises at least:

a substrate;

an anode layer disposed on the substrate;

a pixel definition layer covering the sacrificial layer and the anode layer, the pixel definition layer defines a light-emitting area opening, and the sacrificial layer is formed with a groove at a position corresponding to the light-emitting area opening; and

a light-emitting functional layer disposed in the groove and the light-emitting area opening.

In some embodiments, the sacrificial layer comprises at least one of an amphoteric metal, an amphoteric oxide, or an alloy of amphoteric metals.

In some embodiments, the sacrificial layer is aluminum, zinc, aluminum oxide, zinc oxide, or aluminum-zinc alloy.

In some embodiments, the sacrificial layer comprises a first sacrificial layer and a second sacrificial layer, the first sacrificial layer corresponds to the light-emitting area opening, the second sacrificial layer is located between the pixel definition layer and the anode layer, and a thickness of the first sacrificial layer is less than a thickness of the second sacrificial layer.

In some embodiments, a depth of the groove is equal to a thickness of the sacrificial layer, and the light-emitting functional layer is connected with the anode layer.

In some embodiments, the anode layer comprises:

a first transparent electrode;

a reflective layer disposed on the first transparent electrode; and

a second transparent electrode disposed on the reflective layer.

In some embodiments, the display panel comprises a thin film transistor area and a capacitance area, and the display panel further comprises:

a first metal layer disposed on the substrate, the first metal layer comprises a first electrode disposed in the capacitance area;

a semiconductor layer disposed on the first metal layer, the semiconductor layer comprises a second electrode disposed in the capacitance area; and

a second metal layer disposed on the semiconductor layer, the second metal layer comprises a third electrode disposed in the capacitance area;

wherein the second electrode is disposed above the first electrode, and the third electrode is disposed above the second electrode.

In another aspect, the present application provides a method for manufacturing a display panel, wherein the method comprises:

providing a substrate;

forming an anode layer on the substrate;

forming a sacrificial layer on the anode layer;

forming an initial pixel definition layer covering the sacrificial layer and the anode layer;

exposing and developing the initial pixel definition layer to define a light-emitting area opening to form a pixel definition layer, and etching the sacrificial layer exposed to the light-emitting area opening to form a groove; and

forming a light-emitting functional layer in the groove and the light-emitting area opening

In some embodiments, the step of etching the sacrificial layer exposed to the light-emitting area opening to form a groove comprises:

etching part of the sacrificial layer exposed to the light-emitting area opening, so that a depth of the groove is less than a thickness of the sacrificial layer;

wherein a part of the sacrificial layer is disposed between the light-emitting functional layer and the anode layer.

In some embodiments, wherein the step of etching a sacrificial layer exposed to the opening of the light-emitting area to form a groove comprises:

fully etching the sacrificial layer exposed to the light-emitting area opening, so that a depth of the groove is equal to a thickness of the sacrificial layer;

wherein the light-emitting functional layer is connected with the anode layer.

Beneficial effects of the present application are as follows: providing a display panel and a manufacturing method thereof, wherein the display panel comprises an anode layer, a sacrificial layer, a pixel definition layer, and a light-emitting functional layer. The sacrificial layer is disposed on the anode layer, the pixel definition layer covers the sacrificial layer and the anode layer, and the sacrificial layer is formed with a groove at a position corresponding to the light-emitting area opening, and the light-emitting functional layer is disposed in the groove and the light-emitting area opening. In this way, the sacrificial layer forming at the light-emitting area opening can be removed to form a groove at the same time in the process of forming the light-emitting area opening by exposure and development, so that it is possible to ensure that no pixel definition layer remains on the anode layer at the light-emitting area opening, thereby solving the problem that the light-emitting functional layer cannot be spread, and saving the process cost.

### BRIEF DESCRIPTION OF THE DRAWINGS

The technical solutions and other beneficial effects of the present application will be apparent from detailed description of specific embodiments of the present application with reference to the accompanying drawings.

FIG. 1 is a schematic structural diagram of a display panel according to an embodiment of the present application;

FIG. 2 is a schematic structural diagram of a display panel according to another embodiment of the present application;

FIG. 3 is schematic structural diagram of an enlarged structure at position A in FIG. 2;

FIG. 4 is a schematic flowchart of a method for manufacturing a display panel according to an embodiment of the present application; and

FIGS. 5a-5h are schematic structural diagrams of a display panel in a manufacturing process according to an embodiment of the present application.

### DETAILED DESCRIPTION

Hereinafter, technical solution in embodiments of the present application will be clearly and completely described with reference to the accompanying drawings in embodiments of the present application. Apparently, the described embodiments are part of, but not all of, the embodiments of the present application. All the other embodiments, obtained by a person with ordinary skill in the art on the basis of the embodiments in the present application without expenditure of creative labor, belong to the protection scope of the present application.

In description of the present application, it should be understood that the terms “first”, “second” are used for descriptive purposes only and cannot be understood as indicating or implying relative importance or implicitly indicating the number of indicated technical features. Thus, the features defined by “first” and “second” may explicitly or implicitly comprise one or more features. In description of the present application, “a plurality of” means two or more, unless specifically limited otherwise.

In the present application, unless specified and limited otherwise, a first feature “on” or “under” a second feature may comprise direct contact of the first feature and the second feature, and it may also be comprised that the first feature and the second feature are not in direct contact but are contacted by additional features between them. Moreover, the first feature “on”, “above” and “upper” the second feature comprises the first feature directly above and obliquely upward the second feature, or merely indicates that a level of the first feature is higher than a level of the second feature. The first feature “lower”, “below” and “under” the second feature comprises the first feature directly below and obliquely downward the second feature, or merely indicates that a level of the first feature is less than a level of the second feature.

The following disclosure provides many different embodiments or examples for realizing different structures of the present application. In order to simplify the disclosure of the present application, components and settings of specific examples are described below. Of course, they are merely examples and are not intended to limit the present application. In addition, reference numbers and/or letters may be repeated in different examples of the present application. Such repetitions are for simplification and clearness, which per se do not indicate the relations of the discussed embodiments and/or settings. Moreover, the present application provides examples of various specific processes and materials, but the applicability of other processes and/or application of other materials may be appreciated by a person skilled in the art.

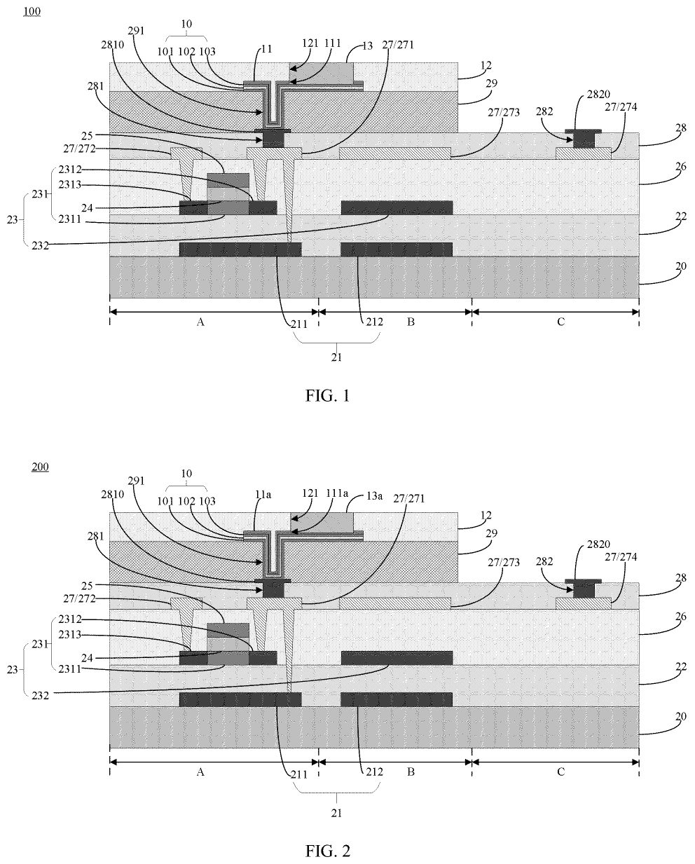

Referring to FIG. 1, which is a schematic structural diagram of a display panel according to an embodiment of the present application. The display panel 100 can be applied to an organic light-emitting diode (OLED).

The display panel 100 comprises at least an anode layer 10, a sacrificial layer 11, a pixel definition layer 12, and a light-emitting functional layer 13. The sacrificial layer 11 is disposed on the anode layer 10, and the pixel definition layer 12 covers the sacrificial layer 11 and the anode layer 10. The pixel definition layer 12 defines a light-emitting area opening 121, the sacrificial layer 11 is formed with a groove 111 at a position corresponding to the light-emitting area opening 121, and the light-emitting functional layer 13 is disposed in the groove 111 and the the light-emitting area opening 121.

In some embodiments, the anode layer 10 may comprise a first transparent electrode 101, a reflective layer 102 disposed on the first transparent electrode 101, and a second transparent electrode 103 disposed on the reflective layer 102. Materials of the first transparent electrode 101 and the second transparent electrode 103 may be indium tin oxide (ITO), or may be other transparent conductive films, such as indium zinc oxide (IZO). Materials of the reflective layer 102 may be silver, aluminum, or an aluminum alloy.

In some embodiments, the sacrificial layer 11 may comprise at least one of an amphoteric metal (such as aluminum and zinc), an amphoteric oxide (such as aluminum oxide and zinc oxide), or an alloy of amphoteric metals (such as aluminum alloy and zinc alloy).

In some embodiments, the light-emitting functional layer 13 may comprise a hole injection layer, a hole transport layer, a light-emitting layer, an electron transport layer, and an electron injection layer. The display panel 100 may further comprise a cathode layer (not shown) disposed on the light-emitting functional layer 13 and the pixel definition layer 12.

As shown in FIG. 1, the light-emitting area opening 121 exposing the anode layer 10 is formed in the pixel definition layer 12, and the groove 111 is formed on the sacrificial layer 11 at a position corresponding to the light-emitting area opening 121. The groove 111 communicates with the light-emitting area opening 121, and a bottom area of the groove 111 is equal to a bottom area of the light-emitting area opening 121. A depth of the groove 111 in the direction perpendicular to the film thickness is equal to a thickness of the sacrificial layer 11, that is, the sacrificial layer 11 exposed to the light-emitting area opening 121 is completely removed to expose the lower second transparent electrode 103.

In some embodiments, the display panel 100 may further comprise a substrate 20, a first metal layer 21, a buffer layer 22, a semiconductor layer 23, a gate insulating layer 24, a gate layer 25, an interlayer dielectric layer 26, and a second metal layer 27. The display panel 100 may comprise a display area and a binding area C, wherein the display area comprises a thin film transistor area A and a capacitance area B between the thin film transistor area A and the binding area C. The first metal layer 21 comprises a light shielding layer 211 disposed in the thin film transistor area A and a first electrode 212 disposed in the capacitance area B. The semiconductor layer 23 comprises an active layer 231 disposed in the thin film transistor area A and a second electrode 232 disposed in the capacitance area B, wherein the second electrode 232 is correspondingly disposed above the first electrode 212. The active layer 231 may comprise a channel area 2311, a source contact area 2312 and a drain contact area 2313 disposed on both sides of the channel area 2311, and the second electrode 232 may be a conductive semiconductor layer. The second metal layer 27 comprises a source 271 and a drain 272 disposed in the thin film transistor area A, a third electrode 273 disposed in the capacitance area B, and a binding structure 274 disposed in the binding area C, wherein the third electrode 273 is disposed correspondly above the second electrode 232. The first electrode 212 and the third electrode 273 may be connected in series, the first electrode 212 and the second electrode 232 form a storage capacitance, and the third electrode 273 and the second electrode 232 form a storage capacitance, so that the first electrode 212, the second electrode 232 and the third electrode 273 may form a double capacitance to increase the storage capacity.

The first metal layer 21 is disposed on the substrate 20, the buffer layer 22 is disposed on the substrate 20 and covers the first metal layer 21, and the semiconductor layer 23 is disposed on the buffer layer 22. The gate insulating layer 24 is disposed on the semiconductor layer 23, specifically on the active layer 231, the gate layer 25 is disposed on the gate insulating layer 24, and the interlayer dielectric layer 26 is disposed on the buffer layer 22 and covers the gate layer 25, the gate insulating layer 24 and the semiconductor layer 23. The second metal layer 27 is disposed on the interlayer dielectric layer 26, wherein the source 271 is connected to the source contact area 2312 through a first via, the drain 272 is connected to the drain contact area 2313 through a second via, and the source 271 is also connected to the underlying light shielding layer 211 through a third via.

The substrate 20 may comprise one or a combination of a rigid substrate (such as glass) and a flexible substrate (such as polyimide, polyethylene terephthalate, etc.). The first metal layer 21 comprises, but is not limited to, Mo, Ti, Cu, Mn or alloys thereof, a laminated structure of Mo, Al and Mo (Mo/Al/Mo), and a laminated structure of Mo, Ti and Cu (Mo/Ti/Cu). The buffer layer 22 may be a single-layer structure made of one of SiOx, SiNx, and SiNO, or a laminated structure made of SiNx/SiOx. The semiconductor layer 23 may be a metal oxide semiconductor layer (such as IGZO, IZTO, IGZTO, etc.) or amorphous silicon, wherein materials of the source contact area 2312, the drain contact area 2313, and the second electrode 232 may be N-type ion-doped oxide semiconductor layers or N-type ion-doped amorphous silicon. Materials of the gate insulating layer 24 may be SiOx, SiNx, Al₂O₃/SiNx/SiOx, SiOx/SiNx/SiOx, or the like. Materials of the gate layer 25 may comprise Mo, Ti, Cu or Mo/Al or Mo/Cu or Mo/Cu/IZO or IZO/Cu/IZO or Mo/Cu/ITO or Ni/Cu/Ni or MoTiNi/Cu/MoTiNi or NiCr/Cu/NiCr or CuNb or the like. The interlayer dielectric layer 26 may be made of an inorganic material such as one of SiOx, SiNx, and SiNO. Materials of the second metal layer 27 may be Mo or Al/Mo or Mo/Al/Mo or Mo/Cu or/MoTi/Cu or Mo/Cu/IZO or IZO/Cu/IZO or Mo/Cu/ITO or Ni/Cu/Ni or MoTiNi/Cu/MoTiNi or NiCr/Cu/NiCr or CuNb or the like.

In some embodiments, the display panel 100 may further comprise a passivation layer 28 and a planarization layer 29 disposed on the passivation layer 28. Materials used for the passivation layer 28 may be SiOx, SiNx, Al₂O₃/SiNx/SiOx, SiOx/SiNx/SiOx, etc., and materials of the planarization layer 29 and the pixel definition layer 12 may be organic materials. The passivation layer 28 is disposed on the interlayer dielectric layer 26, and the passivation layer 28 is formed with a first opening 281 exposing the source 271 and a second opening 282 exposing the binding structure 274. The planarization layer 29 is disposed in the thin film transistor area A and the capacitance area B, and the pixel definition layer 12 is disposed on the planarization layer 29 and also disposed in the thin film transistor area A and the capacitance area B.

The display panel 100 may further comprise a first connection layer 2810 located in the first opening 281 and a second connection layer 2820 located in the second opening 282. A third opening 291 exposing the first connection layer 2810 is formed in the planarization layer 29, and the anode layer 10 is formed in the third opening 291 and on the surface of the planarization layer 29 and is further connected to the source 271 through the first connection layer 2810. The second connection layer 2820 is connected to the binding structure 274, and the second connection layer 2820 may be bound with a chip on film (COF).

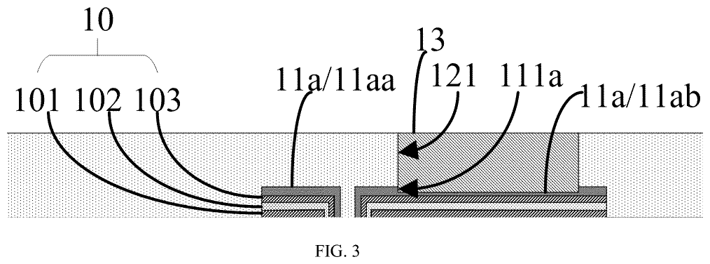

Referring to FIGS. 2 and 3, FIG. 2 is a schematic structural diagram of a display panel according to another embodiment of the present application, and FIG. 3 is schematic structural diagram of an enlarged structure at position A in FIG. 2. For ease of understanding and brief description, the same reference numerals are used for the same structures in this embodiment as in the above-described embodiment, and the same structure is omitted here.

In the display panel 200 provided in the this embodiment, a depth of of the groove 111a formed in the sacrificial layer 11a is less than a thickness of the sacrificial layer 11a, that is, only a part of the surface of the sacrificial layer 11a exposed to the light-emitting area opening 121 is removed, so that there is still a part of the sacrificial layer 11a remaining between the light-emitting functional layer 13a and the anode layer 10 (or the second transparent electrode 103). In order to enable the subsequent light-emitting functional layer 13a to perform ink-jet printing better, the flatness of the surface of the remaining sacrificial layer 11a is required to be high. In order to avoid influence of the sacrificial layer 11a on the light transmittance, the material of the sacrificial layer 11a is preferably transparent.

Since the groove 111a is formed in the sacrificial layer 11a, and the depth of the groove 111a formed in the sacrificial layer 11a is less than the thickness of the sacrificial layer 11a, the sacrificial layer 11a may comprise a first sacrificial layer 11aa located between the pixel-defination layer 12 and the anode layer 10 and a second sacrificial layer 11ab located between the light-emitting functional layer 13 and the anode layer 10, and a thickness of the first sacrificial layer 11aa is greater than a thickness of the second sacrificial layer 11ab.

An embodiment of the present application provides a display panel comprising an anode layer 10, a sacrificial layer, a pixel definition layer 12, and a light-emitting functional layer. The sacrificial layer is disposed on the anode layer 10, and the pixel definition layer 12 covers the sacrificial layer and the anode layer 10. In this way, the sacrificial layer forming at the light-emitting area opening 121 can be removed to form a groove at the same time in the process of forming the light-emitting area opening by exposure and development, and the depth of the grooves can be less than or equal to the thickness of the sacrificial layer, that is, the sacrificial layer exposed to the light-emitting area opening 121 can be completely removed or only a part of the surface can be removed. Therefore, it is possible to ensure that no pixel definition layer 12 remains on the anode layer 10 at the light-emitting area opening 121, thereby solving the problem that the light-emitting functional layer located in the groove and the light-emitting area opening 121 cannot be spread, improving the product yield, and further saving the process cost.

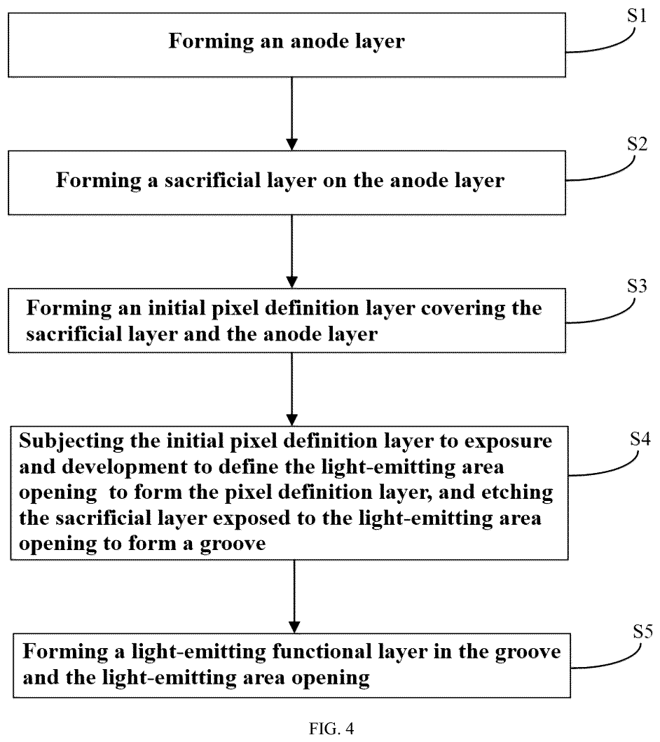

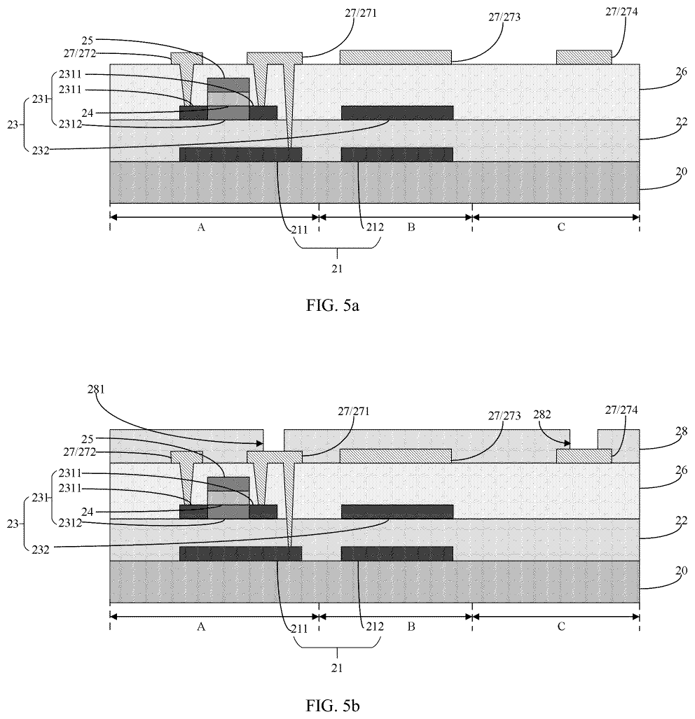

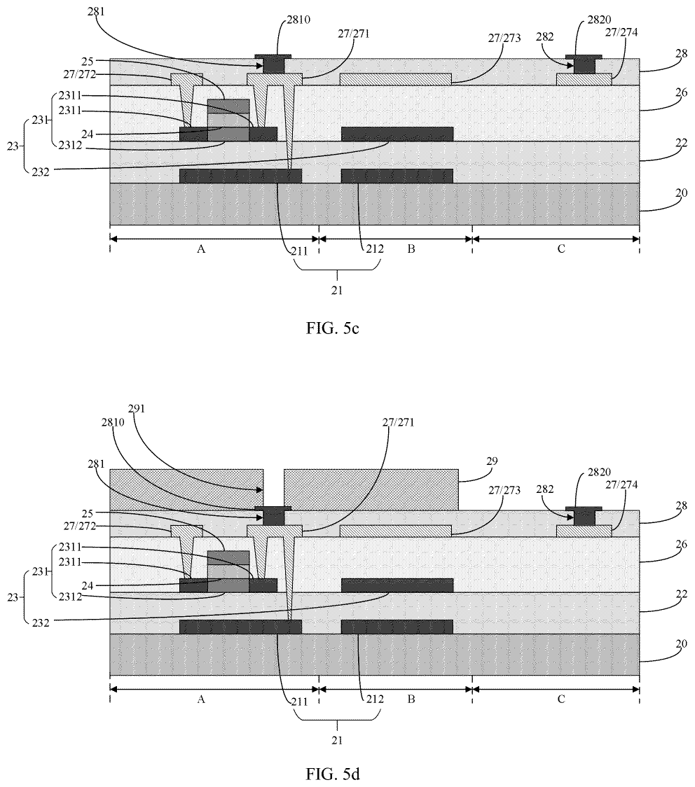

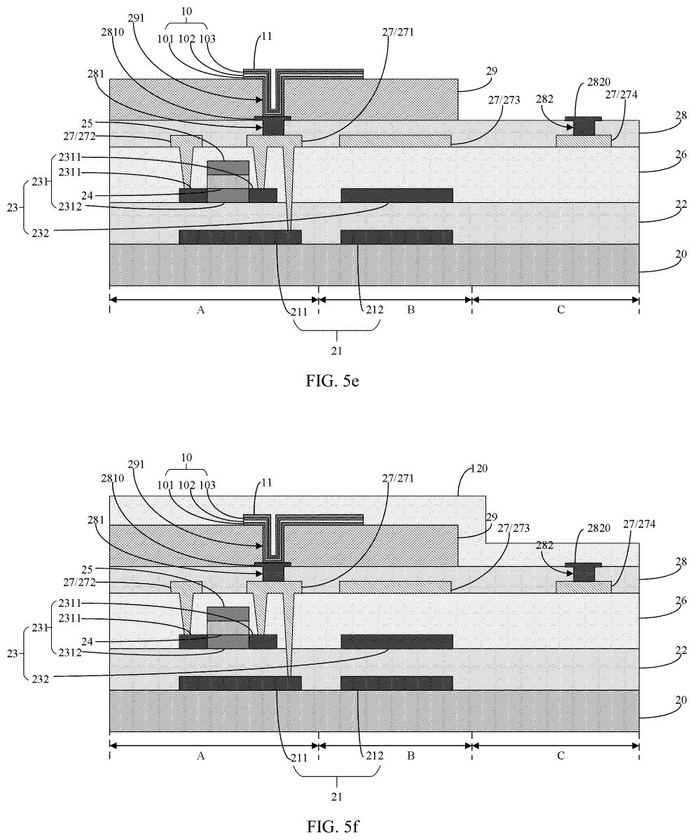

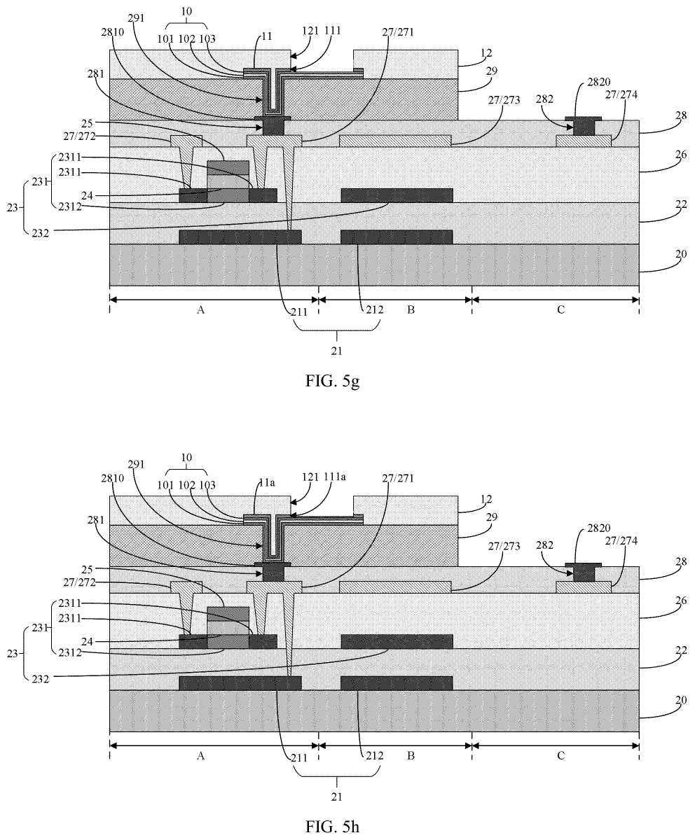

Referring to FIG. 4, which is a flowchart of a method for manufacturing a display panel according to an embodiment of the present application. Referring to FIGS. 5a-5h, which are schematic structural diagrams of a display panel in a manufacturing process according to an embodiment of the present application. In this embodiment, the above-described display panel 100 and 200 are manufactured as examples, and the method for manufacturing the display panel is described. The manufacturing method comprises the following steps S1-S5.

Referring to step S1 in FIG. 4 and FIGS. 5a-5e.

Step S1: forming an anode layer 10.

As shown in FIG. 5a, 1) firstly, depositing a first metal layer 21 on the substrate 20, and then depositing a buffer layer 22 on the first metal layer 21. Next, depositing an initial semiconductor layer on the buffer layer 22, and patterning the initial semiconductor layer to form a first initial semiconductor layer located in the thin film transistor area A and a second initial semiconductor layer located in the capacitance area B.

2) Sequentially depositing an initial gate insulating layer and an initial gate layer on the first initial semiconductor layer, the second initial semiconductor layer, and the buffer layer 22. Forming the gate layer 25 on the first initial semiconductor layer by etched using a mask, and then etching the initial gate insulating layer by using the gate layer 25 for self-alignment. Therefore, the gate insulating layer 24 is formed only by the presence of the initial gate insulating layer below the gate layer 25, and the initial gate insulating layer elsewhere is etched away.

3) Performing an N-type ion implantation on the entire surfaces of the first initial semiconductor layer and the second initial semiconductor layer. For the first initial semiconductor layer which is not protected by the gate insulating layer 24, the resistance is obviously reduced after treatment to form the source contact area 2312 and the drain contact area 2313. The first initial semiconductor layer below the gate insulating layer 24 is not processed to maintain the semiconductor characteristics to form the channel area 2311, and the source contact area 2312, the drain contact area 2313, and the channel area 2311 form the active layer 231. The second initial semiconductor layer is processed to form the second electrode 232, and the active layer 231 and the second electrode 232 form the semiconductor layer 23.

4) An interlayer dielectric layer 26 covering the gate layer 25, the gate insulating layer 24, and the semiconductor layer 23 is formed by a deposition process, a contact hole is etched in the buffer layer 22 by a mask, and a contact hole is etched in the interlayer dielectric layer 26 by a mask, so that a first via hole and a second via hole which respectively expose the source contact area 2312 and the drain contact area 2313 are formed in the interlayer dielectric layer 26, and a third via hole exposing the light shielding layer 211 is formed in the interlayer dielectric layer 26 and the buffer layer 22.

5) Finally, depositing a layer of metal on the interlayer dielectric layer 26, followed by patterning patterning to form the second metal layer 27, wherein the source 271 is connected to the source contact area 2312 through the first via, the drain 272 is connected to the drain contact area 2313 through the second via, and the source 271 is further connected to the light shielding layer 211 through the third via.

As shown in FIG. 5b, a passivation layer 28 is deposited on the interlayer dielectric layer 26 and the second metal layer 27, followed by patterning to form a first opening 281 exposing the source 271 and a second opening 282 exposing the binding structure 274.

As shown in FIG. 5c, connection layers are deposited on the first opening 281, the second opening 282, and the passivation layer 28, followed by patterning to form a first connection layer 2810 in the first opening 281 and a second connection layer 2820 in the second opening 282.

As shown in FIG. 5d, a planarization layer 29 is formed by a deposition process and a patterned etching process, the planarization layer 29 is located in the thin film transistor area A and the capacitance area B, and a third opening 291 exposing the first connection layer 2810 is formed in the planarization layer 29. The planarization layer 29 may adopt one or two film layers.

As shown in FIG. 5e, the anode layer 10 is deposited on the third opening 291 and the planarization layer 29, and a patterned etching process is performed. The anode layer 10 may comprise a first transparent electrode 101, a reflective layer 102, and a second transparent electrode 103, which are sequentially deposited.

Referring to steps S2 in FIG. 4 and FIG. 5e.

Step S2: forming a sacrificial layer 11 on the anode layer 10.

After the step of depositing the anode layer 10, the sacrificial layer 11 is deposited on the anode layer 10 and then subjected to a patterned etching process together with the anode layer 10. The sacrificial layer 11 may comprise at least one of an amphoteric metal (such as aluminum and zinc), an amphoteric oxide (such as aluminum oxide and zinc oxide), or an alloy of amphoteric metals (such as aluminum alloy and zinc alloy). Some inorganic acids may be used to etch both the anode layer 10 and the sacrificial layer 11 in the patterned etching process.

Referring to step S3 in FIG. 4 and FIG. 5f.

Step S3: forming an initial pixel definition layer 120 covering the sacrificial layer 11 and the anode layer 10.

Specifically, depositing the initial pixel definition layer 120 on the passivation layer 28, the planarization layer 29, and the sacrificial layer 11 by using a deposition process.

Referring to step S4 in FIG. 4 and FIGS. 5g-5h.

Step S4: subjecting the initial pixel definition layer 120 to exposure and development to define the light-emitting area opening 121 to form the pixel definition layer 12, and etching the sacrificial layer 11 exposed to the light-emitting area opening 121 to form a groove 111.

The initial pixel definition layer 120 may be made of an organic photoresist material, so the initial pixel definition layer 120 may be patterned by using a photolithographic process. Specifically, the initial pixel definition layer 120 is exposed and developed by using a mask, and the developer used may be 2.38% tetramethyl ammonium hydroxide (TMAH), which is strongly basic. The developor may react with the initial pixel definition layer 120 and the sacrificial layer 11 at the same time, so that a part or all of the sacrificial layer 11 may be removed after the light-emitting area opening 121 is formed to form the groove 111. The structure in which the sacrificial layer 11 is completely removed is shown in FIG. 5g, in which the depth of the groove 111 is equal to the thickness of the sacrificial layer 11, and the subsequently formed light-emitting functional layer 13 is directly connected with the anode layer 10 (see FIG. 1). The structure in which a part of the sacrificial layer 11a is removed from the surface is shown in FIG. 5h, in which the depth of the groove 111a is less than the thickness of the sacrificial layer 11a, and a part of the sacrificial layer 11a is formed between the subsequently formed light-emitting functional layer 13a and the anode layer 10 (see FIG. 2).

Referring to step S5 in FIG. 4 and FIGS. 1-2.

Step S5: forming a light-emitting functional layer 13/13a in the groove 111/111a and the light-emitting area opening 121.

The light-emitting functional layer 13/13a may comprise a hole injection layer, a hole transport layer, a light-emitting layer, an electron transport layer, and an electron injection layer that are sequentially formed from bottom to top. The hole injection layer, the hole transport layer, and the light-emitting layer may adopt an ink-jet printing process. The electron transport layer and the electron injection layer may adopt an evaporation process or a sputtering process. The structure after forming the light-emitting functional layer 13/13a is shown in FIGS. 1 and 2, the light-emitting functional layer 13 in FIG. 1 is connected to the second transparent electrode 103 in the anode layer 10, and a part of the sacrificial layer 11a is provided between the light-emitting functional layer 13a in FIG. 2 and the second transparent electrode 103.

As the initial pixel definition layer 120 is exposed and developed, it is easy to generate tiny residues, and the initial pixel definition layer 120 has a hydrophobic property, so printing materials can't be spread in the subsequent printing of light-emitting functional layers (such as hole injection layer, hole transport layer, and light-emitting layer), which will lead to defects such as dark spots or uneven light emission, thereby affecting the product yield. In embodiments of the present application, a sacrificial layer 11/11a is added to the anode layer 10, and the initial pixel definition layer 120 is located on the sacrificial layer 11/11a even if it remains, and the sacrificial layer 11/11a can be removed during development of the initial pixel definition layer 120. Whether all the sacrificial layers 11 exposed to the light-emitting area openings 121 are removed or some of the sacrificial layers 11a exposed to the light-emitting area openings 121 are removed, the initial pixel definition layer 120 remaining on the sacrificial layer 11/11a can be completely removed, and the subsequent printing of the light-emitting functional layers 13/13a will not be affected by residues. Therefore, the problem that printing materials cannot be spread can be avoided, the product yield can be improved, and the process cost can be saved.

The description of the aforesaid embodiments is only used to help understand the technical solution of the present application and the core idea thereof. A person skilled in the art shall understand that it is still possible to modify the technical solutions described in the above embodiments, or equivalently substitute some of the technical features thereof. However, these modifications or substitutions do not make the essence of the corresponding technical solutions depart from scopes of the technical solutions of each embodiment of the present application.

What is claimed is:

1. A display panel, wherein the display panel comprises at least:
a substrate;
an anode layer disposed on the substrate;
a sacrificial layer disposed on the anode layer;
a pixel definition layer covering the sacrificial layer and the anode layer, the pixel definition layer defines a light-emitting area opening, and the sacrificial layer is formed with a groove at a position corresponding to the light-emitting area opening; and
a light-emitting functional layer disposed in the groove and the light-emitting area opening.

2. The display panel according to claim 1, wherein the sacrificial layer comprises at least one of an amphoteric metal, an amphoteric oxide, or an alloy of amphoteric metals.

3. The display panel according to claim 2, wherein the sacrificial layer is aluminum, zinc, aluminum oxide, zinc oxide, or aluminum-zinc alloy.

4. The display panel according to claim 1, wherein the sacrificial layer comprises a first sacrificial layer and a second sacrificial layer, the first sacrificial layer corresponds to the light-emitting area opening, the second sacrificial layer is located between the pixel definition layer and the anode layer, and a thickness of the first sacrificial layer is less than a thickness of the second sacrificial layer.

5. The display panel according to claim 1, a depth of the groove is equal to a thickness of the sacrificial layer, and the light-emitting functional layer is connected with the anode layer.

6. The display panel according to claim 1, wherein the anode layer comprises:
a first transparent electrode;
a reflective layer disposed on the first transparent electrode; and
a second transparent electrode disposed on the reflective layer.

7. The display panel according to claim 1, wherein the display panel comprises a thin film transistor area and a capacitance capacitance area, and the display panel further comprises:
a first metal layer disposed on the substrate, the first metal layer comprises a first electrode disposed in the capacitance area;
a semiconductor layer disposed on the first metal layer, the semiconductor layer comprises a second electrode disposed in the capacitance area; and
a second metal layer disposed on the semiconductor layer, the second metal layer comprises a third electrode disposed in the capacitance area;
wherein the second electrode is disposed above the first electrode, and the third electrode is disposed above the second electrode.

8. A method for manufacturing a display panel, wherein the method comprises at least:
providing a substrate;
forming an anode layer on the substrate;
forming a sacrificial layer on the anode layer;
forming an initial pixel definition layer covering the sacrificial layer and the anode layer;
exposing and developing the initial pixel definition layer to define a light-emitting area opening to form a pixel definition layer, and etching the sacrificial layer exposed to the light-emitting area opening to form a groove; and
forming a light-emitting functional layer in the groove and the light-emitting area opening.

9. The method according to claim 8, the step of etching the sacrificial layer exposed to the light-emitting area opening to form a groove comprises:
etching part of the sacrificial layer exposed to the light-emitting area opening, so that a depth of the groove is less than a thickness of the sacrificial layer;
wherein a part of the sacrificial layer is disposed between the light-emitting functional layer and the anode layer.

10. The method according to claim 8, wherein the step of etching a sacrificial layer exposed to the opening of the light-emitting area to form a groove comprises:
fully etching the sacrificial layer exposed to the light-emitting area opening, so that a depth of the groove is equal to a thickness of the sacrificial layer;
wherein the light-emitting functional layer is connected with the anode layer.
